(19) United States
(12) Patent Application Publication
(10) Pub. No.: US 2013/0135829 A1
(43) Pub. Date: May 30, 2013

(54) DISPLAY MODULE

(71) Applicant: Keng-Yi LEE, Hsin-Chu (TW)

(72) Inventor: Keng-Yi LEE, Hsin-Chu (TW)

(73) Assignee: AU Optronics Corporation, Hsin-Chu (TW)

(21) Appl. No.: 13/532,992

(22) Filed: Jun. 26, 2012

(30) Foreign Application Priority Data
Nov. 30, 2011 (TW) 100144049

(51) Int. Cl. H05K 7/00

(52) U.S. Cl. 361/748

(57) ABSTRACT

A display module is disclosed which includes a display panel, a printed circuit board, a flexible printed circuit board interconnecting the display panel and the printed circuit board, and a reinforcing piece interconnecting the display panel and the printed circuit board for supporting the printed circuit board. The reinforcing piece prevents drooping or shifting of the printed circuit board relative to the display panel during assembly or transport, thereby preventing severed wires of the flexible printed circuit board.

### RELATED APPLICATIONS

This application claims priority to Taiwan Application Serial Number 100144049, filed Nov. 30, 2011, which is herein incorporated by reference.

### BACKGROUND

1. Field of Invention

The present invention relates to a display.

2. Description of Related Art

Liquid crystal displays (LCDs) have been widely used in electrical products in recent times due to the rapid progress of optical technology and semiconductor technology. Moreover, with the advantages of high image quality, compact size, light weight, low driving voltage, and low power consumption, LCDs have been introduced into portable computers, personal digital assistants, and color televisions, and are gradually replacing the cathode ray tubes (CRTs) used in conventional displays. As a result, LCDs have become the most widely used display apparatus.

An LCD includes the main elements of a display module, a backlight module, and a frame. The display module includes a display panel, a printed circuit board, and a flexible printed circuit board for interconnecting the display panel and the printed circuit board. Because of the limited strength of the flexible printed circuit board, the printed circuit board easily droops or shifts relative to the display panel, particularly during assembly or transport, such that the printed circuit board hits other components. Furthermore, the concentration of stresses at the interface between the printed circuit board and the flexible printed circuit board during such drooping or shifting may lead to the severing of wires of the flexible printed circuit board, ultimately resulting in display problems.

### SUMMARY

An aspect of the invention provides a display module having a reinforcing piece for supporting the printed circuit board and preventing the printed circuit board from drooping or shifting during assembly or transport.

An embodiment of the invention provides a display module. The display module includes a display panel, a printed circuit board, a flexible printed circuit board interconnecting the display panel and the printed circuit board, and at least one reinforcing piece interconnecting the display panel and the printed circuit board for supporting the printed circuit board. The reinforcing piece can be a bottom polarizer, and the bottom polarizer is adhered on a bottom surface of the display panel, and a part of the bottom polarizer is extended under and fixed on the printed circuit board. The reinforcing piece can be a top polarizer. The top polarizer is adhered on a top surface of the display panel, and a part of the top polarizer is extended above and fixed on the printed circuit board. The reinforcing piece can be a plastic sheet, and the plastic sheet interconnects a top surface of the display panel and a top surface of the printed circuit board or interconnects a bottom surface of the display panel and a bottom surface of the printed circuit board. The reinforcing piece can be a metal sheet, and the metal sheet interconnects a top surface of the display panel and a top surface of the printed circuit board or interconnects a bottom surface of the display panel and a bottom surface of the printed circuit board. A plurality of the reinforcing pieces may be disposed on one or more sides of the flexible printed circuit board. There is a lateral gap between the reinforcing piece and the flexible printed circuit board.

Another embodiment of the invention provides a display module. The display module includes a liquid crystal display panel, a top polarizer, a bottom polarizer, a printed circuit board, and a flexible printed circuit board. The liquid crystal display panel has a thin film transistor substrate, a color filter, and a liquid crystal layer disposed between the thin film transistor substrate and the color filter. The top polarizer is adhered on a top surface of the color filter. The bottom polarizer is adhered on a bottom surface of the thin film transistor substrate. The flexible printed circuit board interconnects the thin film transistor substrate and the printed circuit board, in which the top polarizer or the bottom polarizer includes at least one reinforcing portion extending to the printed circuit board, and the reinforcing portion is fixed on the printed circuit board. A plurality of the reinforcing portion may be disposed on one or more sides of the printed circuit board. There is a lateral gap between the reinforcing portion and the printed circuit board.

The present display module utilizes a reinforcing piece for supporting the printed circuit board in order to prevent drooping or shifting of the printed circuit board relative to the display panel during assembly or transport, thereby preventing severed wires of the flexible printed circuit board. The reinforcing piece can be a plastic sheet or a metal sheet. The reinforcing piece can be a top polarizer or a bottom polarizer, in which the top polarizer or the bottom polarizer has at least one reinforcing portion extended to the printed circuit board. The reinforcing portion can be adhered to or screwed on the printed circuit board.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a partial cross-sectional view of a first embodiment of a display module of the invention;

FIG. 2 is a partial cross-sectional view of a second embodiment of the display module of the invention;

FIG. 3 is a top view of the display module in FIG. 2;

FIG. 4 is a partial cross-sectional view of a third embodiment of the display module of the invention;

FIG. 5 is a top view of the display module of FIG. 4;

FIG. 6 is a partial cross-sectional view of a fourth embodiment of the display module of the invention; and

FIG. 7 is a top view of the display module of FIG. 6.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

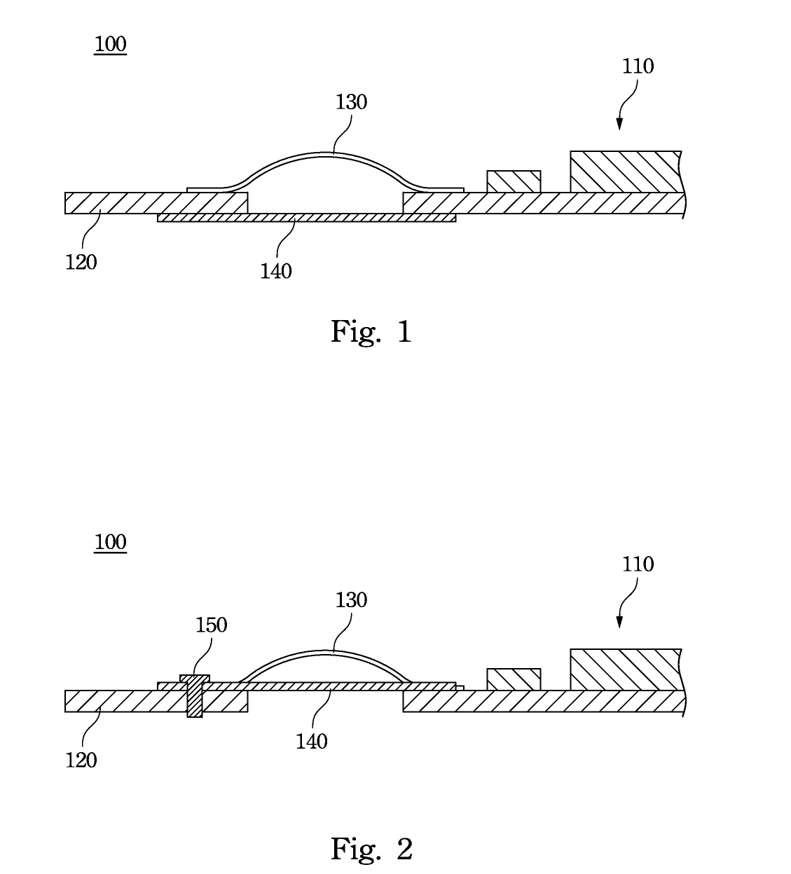

FIG. 1 is a partial cross-sectional view of a first embodiment of a display module of the invention. The display module 100 includes a display panel 110, a printed circuit board 120, and a flexible printed circuit board 130 for interconnecting the printed circuit board 120 and the display panel 110. In order to prevent the printed circuit board 130 from drooping or shifting relative to the display panel 110 during assembly or transport to thereby lead to severed wires of the flexible printed circuit board 130, the display module of the present invention further includes a reinforcing piece 140. The reinforcing piece 140 interconnects the display panel 110 and the printed circuit board 120.

The reinforcing piece 140 is utilized for supporting the printed circuit board 120 in order to prevent drooping or shifting of the printed circuit board 120 during assembly or transport. The reinforcing piece 140 is preferably made of material with enough rigidity for supporting the printed circuit board 120 and preventing the printed circuit board from drooping or shifting. The reinforcing piece 140 can be a plastic sheet or a metal sheet. The reinforcing piece 140 can be disposed under the display panel 110 and the printed circuit board 120, and in this case, the reinforcing piece 140 interconnects the bottom surfaces of the display panel 110 and the printed circuit board 120.

FIG. 2 is a partial cross-sectional view of a second embodiment of the display module of the invention. In this embodiment, the reinforcing piece 140 interconnects the top surfaces of the display panel 110 and the printed circuit board 120. The reinforcing piece 140 can be adhered on the top surfaces of the display panel 110 and the printed circuit board 120. Alternatively, one end of the reinforcing piece 140 can be adhered on the display panel 110, and the other end of the reinforcing piece 140 can be screwed on the printed circuit board 120 with a screw 150.

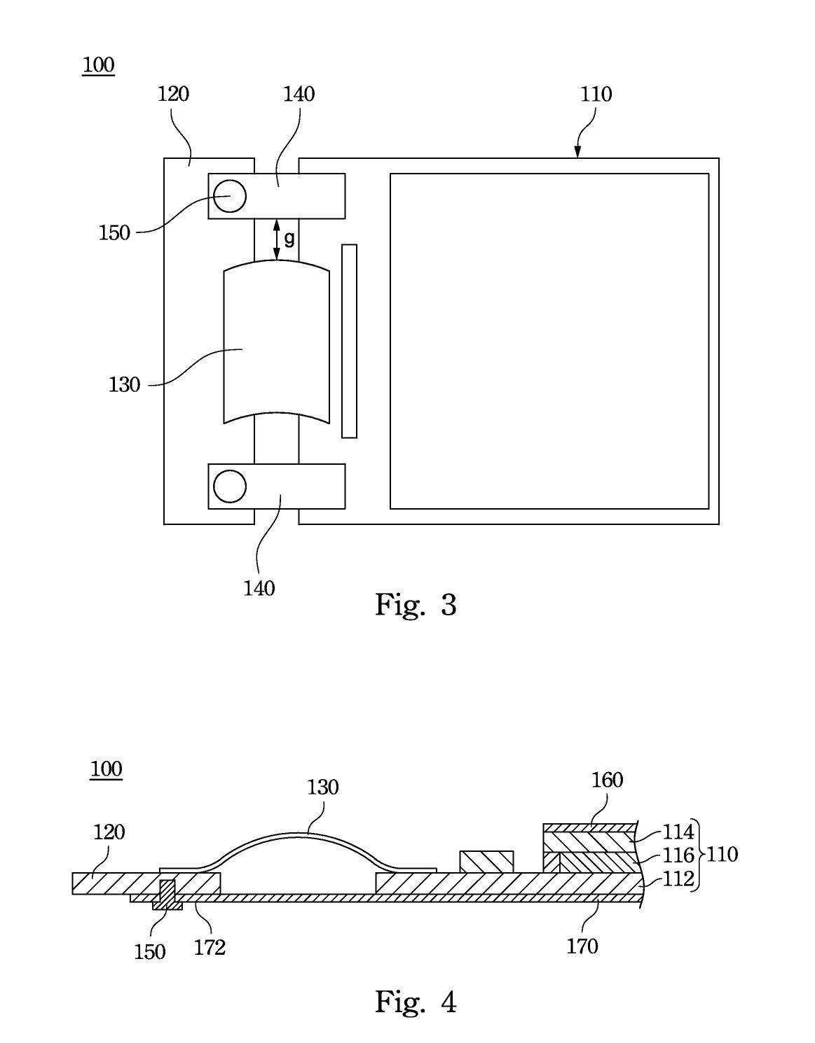

FIG. 3 is a top view of the display module 100 in FIG. 2. One or more reinforcing pieces 140 can be disposed on one side or both sides of the flexible printed circuit board 130. The one or more reinforcing pieces 140 do not overlap the flexible printed circuit board 130 to allow for easy assembly of the flexible printed circuit board 130. More particularly, there is a lateral gap g between each of the one or more reinforcing pieces 140 and the flexible printed circuit board 130 for better positioning of the flexible printed circuit board 140 with an apparatus.

FIG. 4 is a partial cross-sectional view of a third embodiment of the display module of the invention. The display panel 110 can be a liquid crystal display panel. The display panel 110 includes a thin film transistor (TFT) substrate 112, a color filter 114, and a liquid crystal layer 116 disposed between the TFT substrate 112 and the color filter 114. The display module 100 further includes a top polarizer 160 and a bottom polarizer 170 adhered on the display panel 110. More particularly, the top polarizer 160 is adhered on the top surface of the color filter 114, and the bottom polarizer 170 is adhered on the bottom surface of the TFT substrate 112.

Each of the top polarizer 160 and the bottom polarizer 170 has a sufficient support ability and is not easily bent. Therefore the top polarizer 160 and the bottom polarizer 170 can be utilized as the reinforcing piece. For example, a part of the bottom polarizer 170 adhered on the bottom surface of the display module 110 is extended under the printed circuit board 120 and is fixed on the printed circuit board 120. The bottom polarizer 170 has at least one reinforcing portion 172. The reinforcing portion 172 of the bottom polarizer 170 can be adhered on the printed circuit board 120. Alternatively the reinforcing portion 172 can be screwed on the printed circuit board 120 using a screw 150 as shown in FIG. 4.

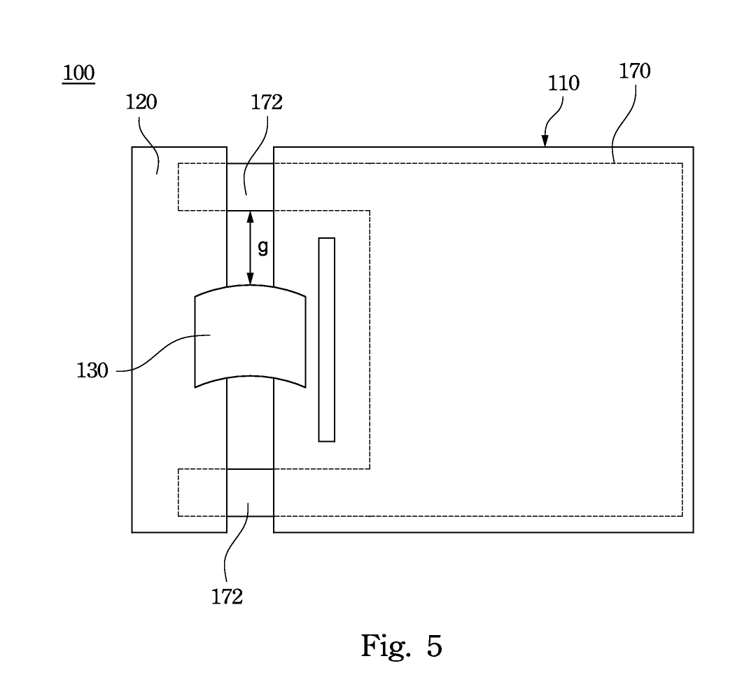

FIG. 5 is a top view of the display module 100 of FIG. 4. The bottom polarizer 170 has one or more reinforcing portions 172. The one or more reinforcing portions 172 can be disposed on one side or opposite sides of the flexible printed circuit board 130. The one or more reinforcing portions 172 do not overlap the flexible printed circuit board 130 to allow for easy assembly of the flexible printed circuit board 130. More particularly, there is a lateral gap g between each of the one or more reinforcing portions 172 and the flexible printed circuit board 130 for better positioning of the flexible printed circuit board 140 with an apparatus. The top polarizer 160 appearing in FIG. 4 is not shown in this figure to simplify the illustration of the display module 100.

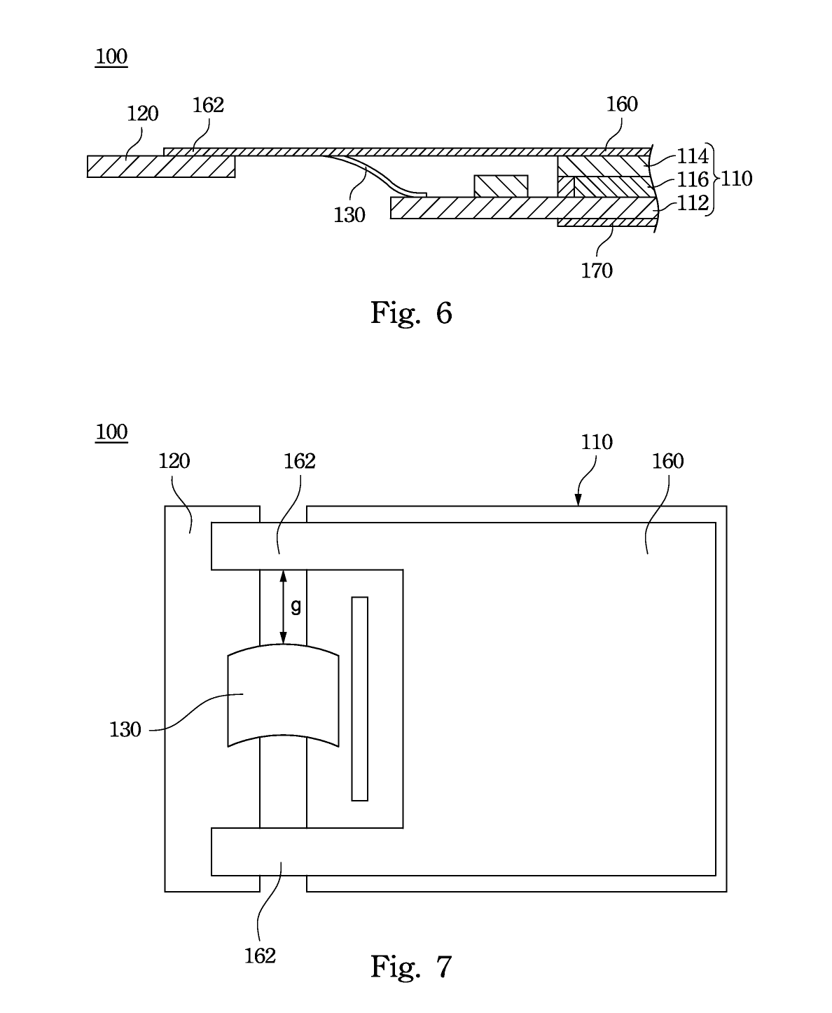

FIG. 6 is a partial cross-sectional view of a fourth embodiment of the display module of the invention. In this embodiment, the top polarizer 160 is utilized as the reinforcing piece. The top polarizer 160 is adhered on the top surface of the display panel 110. The top polarizer 160 has at least one reinforcing portion 162 extended above the printed circuit board 120. The reinforcing portion 162 can be screwed on the printed circuit board 120. Alternatively, the reinforcing portion 162 can be adhered on the printed circuit board 120 as shown in FIG. 6.

FIG. 7 is a top view of the display module 100 of FIG. 6. The top polarizer 160 has one or more reinforcing portions 162 extended to the printed circuit board 120. The one or more reinforcing potions 162 can be disposed on one side or opposite sides of the flexible printed circuit board 130. The one or more reinforcing portions 162 do not overlap the flexible printed circuit board 130 to allow for easy assembly of the flexible printed circuit board 130. More particularly, there is a lateral gap g between each of the one or more reinforcing portions 172 and the flexible printed circuit board 130 for better positioning the flexible printed circuit board 140 with an apparatus.

The present display module utilizes a reinforcing piece for supporting the printed circuit board in order to prevent drooping or shifting of the printed circuit board relative to the display panel during assembly or transport, thereby preventing severed wires of the flexible printed circuit board. The reinforcing piece can be a plastic sheet or a metal sheet. The reinforcing piece can be a top polarizer or a bottom polarizer, in which the top polarizer or the bottom polarizer has at least one reinforcing portion extended to the printed circuit board. The reinforcing portion can be adhered to or screwed on the printed circuit board.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A display module comprising:
a display panel;
a printed circuit board;
a flexible printed circuit board interconnecting the display panel and the printed circuit board; and
at least one reinforcing piece interconnecting the display panel and the printed circuit board for supporting the printed circuit board.

2. The display module of claim 1, wherein the reinforcing piece comprises a bottom polarizer, the bottom polarizer is adhered on a bottom surface of the display panel, and a part of the bottom polarizer is extended under and fixed on the printed circuit board.

3. The display module of claim 1, wherein the reinforcing piece comprises a top polarizer, the top polarizer is adhered on a top surface of the display panel, and a part of the top polarizer is extended above and fixed on the printed circuit board.

4. The display module of claim 1, wherein the reinforcing piece comprises a plastic sheet, and the plastic sheet interconnects a top surface of the display panel and a top surface of the printed circuit board.

5. The display module of claim 1, wherein the reinforcing piece comprises a plastic sheet, and the plastic sheet interconnects a bottom surface of the display panel and a bottom surface of the printed circuit board.

6. The display module of claim 1, wherein the reinforcing piece comprises a metal sheet, and the metal sheet interconnects a top surface of the display panel and a top surface of the printed circuit board.

7. The display module of claim 1, wherein the reinforcing piece to comprises a metal sheet, and the metal sheet interconnects a bottom surface of the display panel and a bottom surface of the printed circuit board.

8. The display module of claim 1, wherein a plurality of the reinforcing pieces are disposed on one or more sides of the flexible printed circuit board.

9. The display module of claim 1, wherein there is at least one lateral gap between the least one reinforcing piece and the flexible printed circuit board.

10. A display module comprising:
a liquid crystal display panel comprising a thin film transistor substrate, a color filter, and a liquid crystal layer disposed between the thin film transistor substrate and the color filter;
a top polarizer adhered on a top surface of the color filter;
a bottom polarizer adhered on a bottom surface of the thin film transistor substrate;
a printed circuit board; and
a flexible printed circuit board interconnecting the thin film transistor substrate and the printed circuit board, wherein the top polarizer or the bottom polarizer comprises at least one reinforcing portion extending to the printed circuit board, and the reinforcing portion is fixed on the printed circuit board.

11. The display module of claim 10, wherein a plurality of the reinforcing portions are disposed on one or more sides of the printed circuit board.

12. The display module of claim 10, wherein there is at least one lateral gap between the least one reinforcing portion and the printed circuit board.
